(19) United States
(12) Patent Application Publication
(10) Pub. No.: US 2018/0374680 A1
(43) Pub. Date: Dec. 27, 2018

(54) PLASMA PROCESSING APPARATUS

(71) Applicant: Tokyo Electron Limited, Tokyo (JP)

(72) Inventor: Taro Ikeda, Yamanashi (JP)

(21) Appl. No.: 16/004,848

(22) Filed: Jun. 11, 2018

(30) Foreign Application Priority Data
Jun. 26, 2017 (JP) 2017-124329

(51) Int. Cl. H01J 37/32; H01L 21/677

(52) U.S. Cl. CPC H01J 37/32311; H01J 37/32238; H01J 2237/327; H01J 37/32743; H01J 37/32788; H01L 21/67739

(57) ABSTRACT

Disclosed is a plasma processing apparatus including a plurality of microwave radiating mechanisms configured to radiate microwaves output from an output unit in a surface wave plasma source into a processing container. The plasma processing apparatus includes a controller configured to generate plasma, while a plasma processing is not performed on a substrate, by radiating microwaves with total power which is 1/50 or less of total power of microwaves per unit area radiated when the plasma processing is performed on the substrate.

### CROSS-REFERENCE TO RELATED APPLICATIONS

This application is based on and claims priority from Japanese Patent Application No. 2017-124329 filed on Jun. 26, 2017 with the Japan Patent Office, the disclosure of which is incorporated herein in its entirety by reference.

### TECHNICAL FIELD

The present disclosure relates to a plasma processing apparatus.

### BACKGROUND

When a wafer is conveyed while plasma is generated, potential of the wafer surface may be made uneven due to the action of the plasma, and a potential difference may occur on the wafer surface in some cases. Then, current flows on the wafer surface, causing a phenomenon in which an element on the wafer surface is destroyed, so-called charge-up damage. In order to prevent charge-up damage from being imparted to a wafer, it is better to convey the wafer while plasma is not generated in a processing container.

On the other hand, at the time of plasma ignition (lighting), electron temperature rapidly rises, and ion impact occurs in the plasma, which may damage the wafer surface. For this reason, it is desirable to avoid igniting the plasma as much as possible while the wafer is being conveyed into the processing container.

Therefore, it has been proposed to gradually increase electric power supplied to a plasma electrode when plasma processing is started (e.g., see Japanese Laid-open Patent Publication No. 2005-064017). Further, it has been proposed to convey wafer without extinguishing the plasma after completing the film forming processing (e.g., see Japanese Laid-open Patent Publication No. 06-291062). Reference is also made to Japanese Laid-open Patent Publication No. 10-144668, Japanese Laid-open Patent Publication No. 2001-335938, and Japanese Laid-open Patent Publication No. 2009-094311.

### SUMMARY

According to one aspect of the present disclosure, a plasma processing apparatus including a plurality of microwave radiation mechanisms configured to radiate microwaves output from an output unit in a surface wave plasma source into a processing container is provided, which plasma processing apparatus including a controller, when plasma processing is not performed on a substrate, configured to generate plasma by radiating microwaves with total power which is 1/50 or less of the total power of microwaves per unit area radiated when plasma processing is performed on the substrate.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a view illustrating an example of a microwave plasma processing apparatus according to an exemplary embodiment.

FIG. 2 is a view illustrating an example of an inner wall of a ceiling plate of a microwave plasma processing apparatus according to an exemplary embodiment.

FIG. 3 is a flowchart illustrating an example of plasma processing according to an exemplary embodiment.

FIGS. 4A and 4B are views for explaining a state of plasma according to an exemplary embodiment.

FIG. 5 is a flowchart illustrating an example of power at plasma ignition according to an exemplary embodiment.

FIG. 6 is a view illustrating an example of electron density and electron temperature of surface wave plasma according to an exemplary embodiment.

FIG. 7 is a view illustrating an example of surface wave plasma and ICP according to an exemplary embodiment.

FIGS. 8A to 8E are views for explaining a microwave introduction sequence according to an exemplary embodiment.

### DETAILED DESCRIPTION

In the following detailed description, reference is made to the accompanying drawing, which form a part hereof. The illustrative embodiments described in the detailed description, drawing, and claims are not meant to be limiting. Other embodiments may be utilized, and other changes may be made without departing from the spirit or scope of the subject matter presented here.

In Japanese Laid-open Patent Publication Nos. 2005-064017 and 06-291062, plasma having a moderate or high electron density and electron temperature is generated using a capacitively coupled plasma (CCP) processing apparatus. Therefore, even though the power to be supplied to the plasma electrode is gradually increased, when a wafer is conveyed while plasma having a moderate or high electron density and electron temperature is generated, the potential of the plasma greatly changes on the wafer surface, so that charge-up damage is caused. Further, when the wafer is conveyed while plasma having a moderate or high electron density and electron temperature is generated, without extinguishing the plasma, the wafer is damaged.

In view of the above problem, in one aspect, the present disclosure suppresses a wafer from being damaged.

In order to solve the above problem, according to one aspect, a plasma processing apparatus including a plurality of microwave radiation mechanisms configured to radiate microwaves output from an output unit in a surface wave plasma source into a processing container is provided. The plasma processing apparatus includes a controller configured to generate plasma by radiating the microwaves with total power which is 1/50 or less of the total power of microwaves per unit area radiated when a plasma processing is performed on the substrate, while the plasma processing is not performed on the substrate.

In the above described plasma processing apparatus, the controller causes the microwaves to be radiated from at least one of the plurality of microwave radiation mechanisms with the total power of 1/50 or less.

In the plasma processing apparatus described above, the plurality of microwave radiation mechanisms are disposed at the center and the outer periphery of the ceiling plate of the processing container. The controller causes microwaves to be radiated from the microwave radiation mechanism at the center, and then causes microwaves to be radiated from at least one of the microwave radiation mechanisms at the outer periphery.

In the plasma processing apparatus described above, the plurality of microwave radiation mechanisms are disposed at the center and the outer periphery of the ceiling plate of the processing container. The controller causes microwaves to be radiated from at least one of the microwave radiation mechanisms at the outer periphery, and then causes microwaves to be radiated from the microwave radiation mechanism at the center.

In the plasma processing apparatus described above, the plurality of microwave radiation mechanisms are disposed at the center and the outer periphery of the ceiling plate of the processing container. The controller causes microwaves to be radiated from the microwave radiation mechanism at the center and from a plurality of the non-adjacent microwave radiation mechanisms disposed in the circumferential direction at the outer periphery, and then causes microwaves to be radiated from at least one of the remaining microwave radiation mechanisms at the outer periphery.

In the plasma processing apparatus described above, the plurality of microwave radiation mechanisms are disposed at the center and the outer periphery of the ceiling plate of the processing container. The controller causes microwaves to be radiated from the plurality of the non-adjacent microwave radiation mechanisms disposed in the circumferential direction at the outer periphery, and then causes microwaves to be radiated from the microwave radiation mechanism at the center and from at least one of the remaining microwave radiation mechanisms at the outer periphery.

In the plasma processing apparatus described above, the plurality of microwave radiation mechanisms are disposed at the center and the outer periphery of the ceiling plate of the processing container. The controller causes microwaves to be radiated from all the disposed microwave radiation mechanisms at the same timing.

In the above described plasma processing apparatus, the controller controls the total power of the microwaves per unit area to 0.3 W/cm² or less while plasma processing is not being performed on the substrate.

In the above described plasma processing apparatus, the controller controls the total power of the microwaves per unit area to 15.6 W/cm² or more while plasma processing is being performed on the substrate.

In the above described plasma processing apparatus, the controller controls the total power of microwaves per unit area to 0.3 W/cm² or less and causes a gate valve to be opened and causes the substrate to be loaded into the processing container while plasma having an electron temperature of 1 [eV] or less is generated. After loading the substrate into the processing container, the controller causes the gate valve to be closed, controls the total power of microwaves per unit area to 15.6 W/cm² or more, and performs plasma processing on the substrate.

In the above described plasma processing apparatus, the controller, after performing the plasma processing, controls the total power of microwaves per unit area to 0.3 W/cm² or less and causes the gate valve to be opened and causes the substrate to be unloaded from the processing container while plasma having an electron temperature of 1 [eV] or less is generated.

According to one aspect, it is possible to suppress a wafer from being damaged.

Hereinafter, an exemplary embodiment of the present disclosure will be described with reference to the drawings. In the present specification and drawings, components having substantially the same configurations will be denoted by the same symbols, and the overlapping descriptions thereof will be omitted.

### [Microwave Plasma Processing Apparatus]

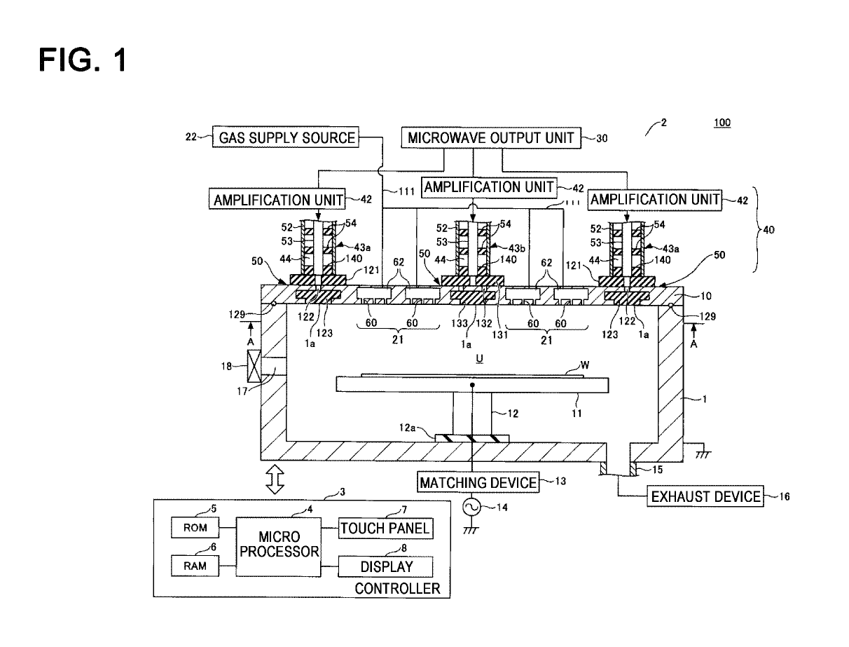

FIG. 1 illustrates an example of a cross-sectional view of a microwave plasma processing apparatus 100 according to an exemplary embodiment of the present disclosure. The microwave plasma processing apparatus 100 includes a processing container (chamber) 1 configured to accommodate a wafer W therein. The microwave plasma processing apparatus 100 is an example of a plasma processing apparatus which performs a predetermined plasma processing on a semiconductor wafer W (hereinafter, referred to as “wafer W”) by surface wave plasma formed on the ceiling surface of the processing container 1 by microwaves. The predetermined plasma processing is, for example, a film forming processing, an etching processing, or an ashing processing.

The microwave plasma processing apparatus 100 includes the processing container 1, a microwave plasma source 2, and a control device 3. The processing container 1 is a substantially cylindrical container configured to be airtight and made of a metal material such as, for example, aluminum or stainless steel, and is grounded. A body portion 10 is a ceiling plate constituting a ceiling portion of the processing container 1. The inside of the processing container 1 is air-tightly sealed by a support ring 129 provided on the contact surface between the upper portion of the processing container 1 and the body portion 10. The body portion 10 is made of a metal.

The microwave plasma source 2 includes a microwave output unit 30, a microwave transmission unit 40, and a microwave radiating mechanism 50. The microwave plasma source 2 is provided to face the inside of the processing container 1 from a dielectric window portion 1a formed on the inner wall of the ceiling portion (ceiling plate) of the processing container 1. The microwave output unit 30 outputs microwaves by distributing the microwaves into a plurality of paths. When the microwaves are introduced from the microwave plasma source 2 into the processing container through the dielectric window portion 1a, the gas in the processing container 1 is dissociated by the electric fields of the microwaves so that surface wave plasma is formed. The microwave output unit 30 is an example of an output unit in the surface wave plasma source.

A placing table 11 is provided in the processing container 1 to place the wafer W thereon. The placing table 11 is supported by a tubular support member 12 erected at the center of the bottom portion of the processing container 1 through an insulating member 12a. Materials constituting the placing table 11 and the support member 12 are, for example, a metal such as, for example, aluminum, having a surface treated by alumite processing (anodizing processing), or an insulating member (e.g., ceramics) having a high frequency electrode therein. The placing table 11 is provided with, for example, an electrostatic chuck configured to electrostatically attract the wafer W, a temperature control mechanism, and a gas flow path configured to supply a heat transfer gas to the back surface of the wafer W.

A high frequency bias power source 14 is electrically connected to the placing table 11 via a matching device 13. Ions in the plasma are drawn into the wafer W side by supplying high frequency power from the high frequency bias power source 14 to the placing table 11. The high frequency bias power source 14 may not be provided depending on the characteristics of the plasma processing.

An exhaust pipe 15 is connected to the bottom portion of the processing container 1 and an exhaust device 16 including a vacuum pump is connected to the exhaust pipe 15. When the exhaust device 16 is operated, the inside of the processing container 1 is evacuated and thus the inside of the processing container 1 is decompressed to the predetermined degree of vacuum at a high speed. The side wall of the processing container 1 is provided with a loading/unloading port 17 configured to load/unload the wafer W and a gate valve 18 that opens/closes the loading/unloading port 17.

The microwave transmission unit 40 transmits microwaves output from the microwave output unit 30. A peripheral edge microwave introduction unit 43a and a central microwave introduction unit 43b provided in the microwave transmission unit 40 have a function of introducing the microwaves output from the amplification unit 42 correspondingly provided to each other to a microwave radiating mechanism 50 and a function of matching impedance. Hereinafter, the peripheral edge microwave introduction unit 43a and the central microwave introduction unit 43b are also collectively referred to as a “microwave introduction unit 43.”

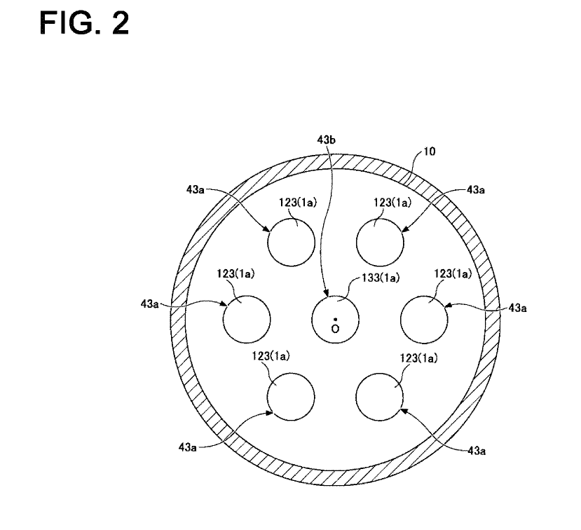

In the microwave radiating mechanism 50 of the exemplary embodiment, as illustrated in FIG. 1 and FIG. 2 which is a cross-sectional view taken along line A-A in FIG. 1, six dielectric layers 123 corresponding to six peripheral edge microwave introduction units 43a are disposed on the outer periphery of the body portion 10 at regular intervals in the circumferential direction and six dielectric window portions 1a are circularly exposed in the processing container 1.

In addition, one dielectric layer 133 corresponding to the central microwave introduction unit 43b is disposed at the center O of the body portion 10 and one dielectric window portion 1a is circularly exposed in the processing container 1. The central microwave introduction unit 43b is disposed at the center O of the body portion 10 at equal distances from the six peripheral edge microwave introduction units 43a.

In the exemplary embodiment, the number of the peripheral edge microwave introduction units 43a is six. However, the number of the peripheral edge microwave introduction unit 43b is not limited thereto and N peripheral edge microwave introduction units 43b are disposed. N may be 1 or 2 or more. However, N may be 3 or more (e.g., 3 to 6).

Returning to FIG. 1, in the peripheral edge microwave introduction units 43a and the central microwave introduction unit 43b, a tubular outer conductor 52 and a rod-shaped inner conductor 53 provided at the center thereof are coaxially arranged. A gap between the outer conductor 52 and the inner conductor 53 is supplied with microwave power and serves as a microwave transmission path 44 through which microwaves propagate toward the microwave radiating mechanism 50.

The peripheral edge microwave introduction units 43a and the central microwave introduction unit 43b are provided with a slag 54 and an impedance adjustment member 140 located at the tip end of the slag 54. By moving the slag 54, the impedance adjustment member 140 has a function of matching the impedance of the load (plasma) inside the processing container 1 with the characteristic impedance of the microwave power source in the microwave output unit 30. The impedance adjustment member 140 is formed of a dielectric material and is adapted to adjust the impedance of the microwave transmission path 44 by the relative dielectric constant of the dielectric material.

The microwave radiating mechanism 50 is provided inside the body portion 10. The microwaves output from the microwave output unit 30 and transmitted from the microwave transmission unit 40 are radiated into the processing container 1 from the microwave radiating mechanism 50.

The microwave radiating mechanism 50 includes dielectric ceiling plates 121 and 131, slots 122 and 132, and dielectric layers 123 and 133. The dielectric ceiling plate 121 is disposed on an upper portion of the body portion 10 in correspondence with the peripheral edge microwave introduction unit 43a and the dielectric ceiling plate 131 is disposed on an upper portion of the body portion 10 in correspondence with the central microwave introduction unit 43b. The dielectric ceiling plates 121 and 131 are formed of a disk-shaped dielectric material that transmits microwaves. The dielectric ceiling plates 121 and 131 have a relative dielectric constant larger than that of vacuum. The dielectric ceiling plates 121 and 131 may be formed of, for example, ceramics such as quartz and alumina (Al₂O₃), fluorocarbon resins such as polytetrafluoroethylene, and polyimide resin-based resins. The dielectric ceiling plates 121 and 131 are made of a material whose relative dielectric constant is larger than vacuum. As a result, the microwave radiating mechanism 50 has a function of making the wavelength of the microwaves transmitting the dielectric ceiling plates 121 and 131 shorter than the wavelength of the microwaves propagating in vacuum and making an antenna including the slots 122 and 132 small.

Under the dielectric ceiling plate 121, the dielectric layer 123 is fitted into an opening of the body portion 10 via the slot 122 formed in the body portion 10. Under the dielectric ceiling plate 131, the dielectric layer 133 is fitted into an opening of the body portion 10 via the slot 132 formed in the body portion 10.

The dielectric layers 123 and 133 function as dielectric windows for uniformly forming surface wave plasma of microwaves on the inner surface of the ceiling portion, and serve as dielectric window portion 1a, respectively. Like the dielectric ceiling plates 121 and 131, the dielectric layers 123 and 133 may be formed of, for example, ceramics such as quartz and alumina (Al₂O₃), fluorocarbon resins such as polytetrafluoroethylene, and polyimide resin-based resins.

The metal of the body portion 10 is provided with a gas introduction unit 21 of a shower structure. A gas supply source 22 is connected to the gas introduction unit 21. The gas supplied from the gas supply source 22 passes through a gas supply pipe 111 and is supplied from a gas diffusion chamber 62 to the processing container 1 through the gas introduction unit 21. The gas introduction unit 21 is an example of a gas shower head that supplies a gas from a plurality of gas supply holes 60 formed on the ceiling portion of the processing container 1. One example of the gas may be a plasma generation gas such as Ar gas, a gas to be decomposed with high energy such as O₂ gas or N₂ gas, or a processing gas such as silane gas.

Each unit of the microwave plasma processing apparatus 100 is controlled by the control device 3. The control device 3 includes a microprocessor 4, read only memory (ROM) 5, and random access memory (RAM) 6. In the ROM 5 or RAM 6, a process sequence of the microwave plasma processing apparatus 100 and a process recipe which is a control parameter are stored. The microprocessor 4 is an example of a controller which controls each unit of the microwave plasma processing apparatus 100 based on a process sequence and a process recipe. Further, the control device 3 includes a touch panel 7 and a display 8, and is capable of displaying an input or a result when performing predetermined control according to the process sequence and the process recipe.

When a plasma processing is performed in the microwave plasma processing apparatus 100 having such a configuration, first, the wafer W is loaded into the processing container 1 from the opened gate valve 18 through the loading/unloading port while the wafer W is held on a conveying arm. The gate valve 18 is closed after loading the wafer W. When the wafer W is conveyed to above the placing table 11, the wafer W is moved from the conveying arm to a pusher pin and placed on the placing table 11 as the pusher pin is lowered. The pressure inside the processing container 1 is maintained at a predetermined degree of vacuum by the exhaust device 16. The processing gas is introduced, in a shower form, from the gas introduction unit 21 to the processing container 1. The microwaves radiated from the microwave radiating mechanism 50 through the peripheral edge microwave introduction unit 43a and the central microwave introduction unit 43b are propagated on the inner surface of the ceiling portion. The gas is dissociated by the electric fields of the microwaves propagated as surface waves, so that the plasma processing is performed on the wafer W by the surface wave plasma generated in the vicinity of the surface of ceiling portion on the processing container 1 side. Hereinafter, a space between the ceiling portion of processing container 1 and the placing table 11 is referred to as a “plasma processing space U.” In the exemplary embodiment, very weak plasma is generated even when the wafer W is conveyed, therefore plasma is always generated. As example of the plasma processing according to the exemplary embodiment will be described below.

### [Plasma Processing]

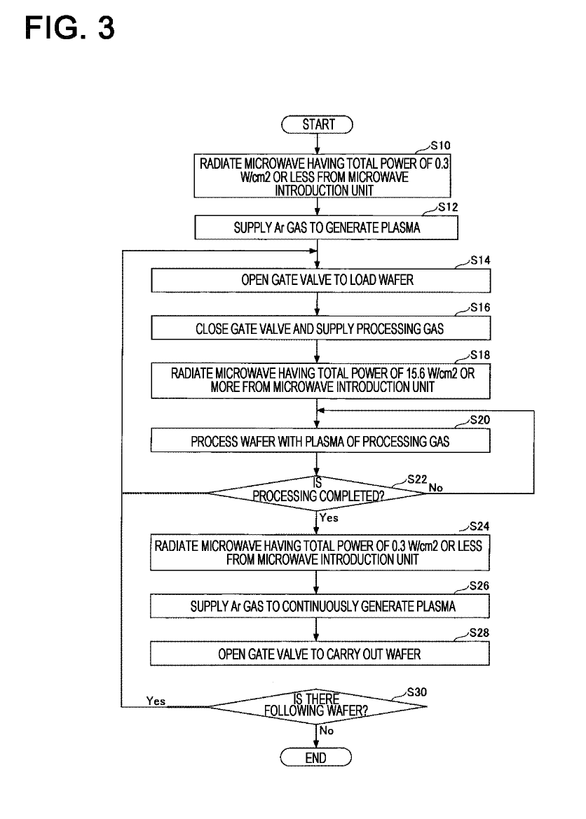

An example of the plasma processing performed using the microwave plasma processing apparatus 100 having such configuration will be described with reference to FIG. 3. The plasma processing according to the exemplary embodiment is controlled by the control device 3.

When the processing is started, the control device 3 controls to radiate microwaves having total power of 0.3 W/cm² or less from the microwave introduction unit 43 (step S10). Next, the control device 3 controls to supply the Ar gas output from the gas supply source 22, in a shower type, from the gas introduction unit 21 and generate plasma (step S12). Further, in step S12, the supplied gas is not limited to the Ar gas, but, for example, may be N₂ gas or the like.

Next, the control device 3 controls to open the gate valve 18 so as to load the wafer W into the processing container 1 (step S14). Next, the control device 3 controls to close the gate valve 18, and supply the processing gas output from the gas supply source 22, in a shower form, from the gas introduction unit 21 (step S16). Further, in step S16, the supplied processing gas may be a mixed gas of silane gas and H₂ gas.

Next, the control device 3 controls to radiate microwaves having total power of 15.6 W/cm² or more from the microwave introduction unit 43 (step S18). As a result, desired processing is performed on the wafer W by the surface wave plasma generated from the processing gas (step S20).

Next, the control device 3 determines whether the plasma processing on the wafer F is completed (step S22). When determining that the plasma processing has not been completed, the control device 3 returns to step S20 and causes the plasma processing to be continued on the wafer W. On the other hand, when determining that the plasma processing on the wafer W is completed, the control device 3 proceeds to step S24 and causes microwaves having total power of 0.3 W/cm² or less to be radiated from the microwave introduction unit 43 (step S24).

Next, the control device 3 causes Ar gas to be supplied from the gas supply source 22 and causes very weak plasma is continuously generated (step S26). Next, the control device 3 causes the gate valve 18 to be opened and causes the wafer W to be unloaded from the processing container 1 (step S28). Next, the controller 3 determines whether there is a following unprocessed wafer (step S30). When determining that there is a following unprocessed wafer, the control device 3 returns back to step S14, and causes the gate valve 18 to be opened, the following wafer W to be loaded into the processing container 1, and the processing after step S14 to be repeated. On the other hand, when determining that there is no following unprocessed wafer, the control device 3 finishes the processing.

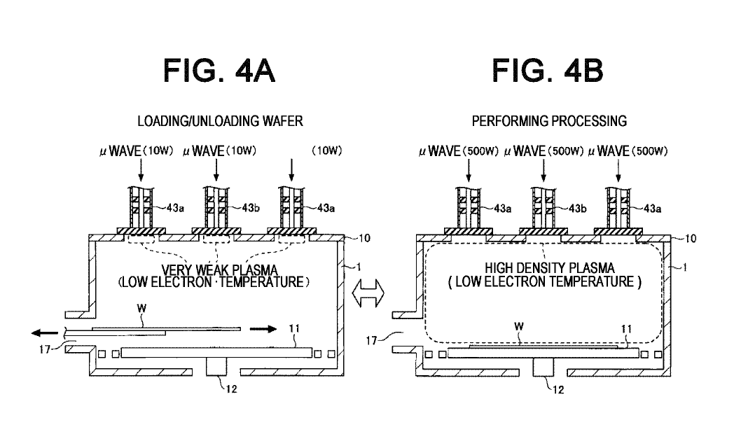

As described above, according to the plasma processing method according to the exemplary embodiment, plasma is continuously generated at all times, including during the conveyance and processing of the wafer W. Specifically, when processing a wafer W having diameter of 300 mm, as illustrated in FIGS. 4A and 4B, during the loading of the wafer W, microwaves having total power of 0.3 W/cm² is radiated in advance from the microwave introduction unit 43 so as to generate very weak plasma. For example, microwaves of 10 W are introduced into the processing container 1 from each of the seven microwave introduction units 43 in total including six peripheral edge microwave introduction units 43a and one central microwave introduction unit 43b. As a result, the Ar gas supplied to the processing container 1 is dissociated by the electric fields of low-power microwaves introduced so that very weak surface wave plasma is generated on the ceiling surface of the processing container 1. Accordingly, since the generated surface wave plasma is very weak, when loading/unloading the wafer, the wafer W is not influenced by the plasma. Therefore, no potential difference occurs on the wafer surface, so that no current flows on the wafer surface. In this way, in the exemplary embodiment, even when loading the wafer W while plasma is being generated, it is possible to avoid damaging the wafer due to plasma.

On the other hand, during the predetermined plasma processing on the wafer W, as illustrated in FIG. 4B, microwaves having total power of 15.6 W/cm² or more is radiated from the microwave introduction unit 43 so as to generate high density plasma. For example, microwaves of 500 W from each of the seven microwave introduction units 43 are introduced into the processing container 1. As a result, the processing gas such as silane gas and H₂ gas is dissociated by the electric fields of microwaves which are 50 times the power at the time of loading the wafer in FIG. 4A, thus high density surface wave plasma is generated on the ceiling surface of the processing container 1. Accordingly, the predetermined plasma processing such as film forming or etching to the wafer W is performed by the generated high density surface wave plasma.

As described above, according to the plasma processing according to the exemplary embodiment, since plasma is always generated, it is not necessary to ignite (light) the plasma before performing the predetermined plasma processing on the wafer W. Therefore, the influence on the wafer W due to plasma ignition may be eliminated. In addition, during the conveyance of the wafer W, very weak plasma is generated so that current flows on the wafer surface by the action of plasma. Thus, no charge-up damage occurs which breaks the element on the surface.

That is, according to the plasma processing method according to the exemplary embodiment, it is possible to avoid occurrence of charge-up damage when conveying the wafer W and eliminate damage to the wafer W due to the plasma ignition when performing the processing.

### [Very Weak Plasma]

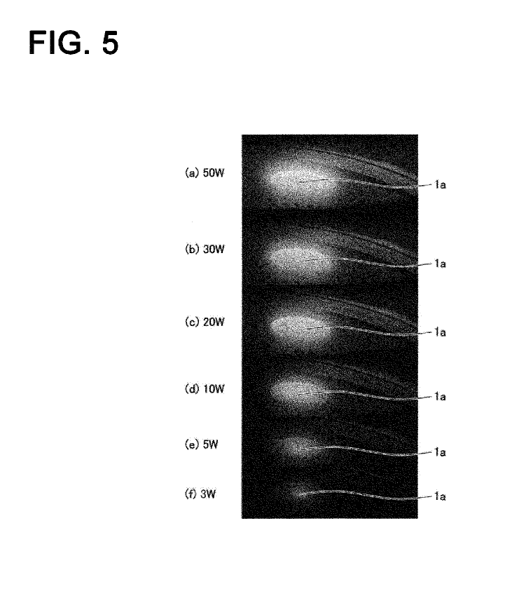

Very weak plasma may be generated by the microwave plasma processing apparatus 100 according to the exemplary embodiment. FIG. 5 illustrates a state of very weak plasma generated in the processing space 1 directly below one microwave introduction unit 43 in a ceiling surface of the microwave plasma processing apparatus 100 (surface wave plasma: SWP) according to the exemplary embodiment. In FIG. 5, emitting portions are seen directly below the dielectric window portion 1a in any of (a) 50 W, (b) 30 W, (c) 20 W, (d) 10 W, (e) 5 W, and (f) 3 W. These portions are emission portions from plasma, and plasma generation regions. That is, very weak plasma is ignited (sparked) directly below the dielectric window portion 1a in any of (a) 50 W to (f) 3 W.

Microwaves having powers of 3 W to 50 W may be output from each of the seven microwave introduction units 43 so that the total power becomes 0.3 W/cm² or less. Microwaves having power whose total power becomes 0.3 W/cm² may be output from one microwave introduction unit 43 or two to six microwave introduction units 43.

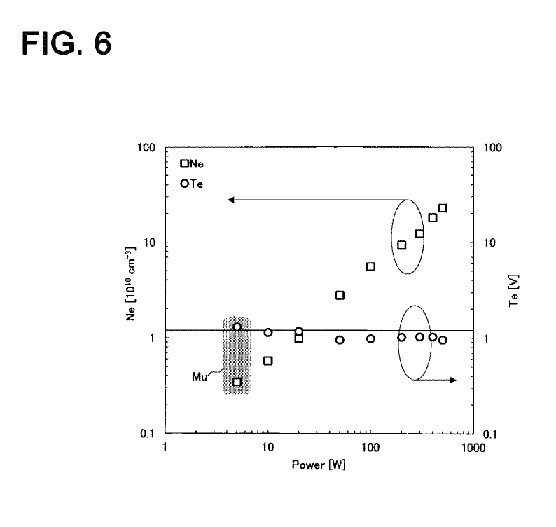

A relationship between the power of introduced microwaves and the electron density Ne [10¹⁰ cm⁻³] of plasma and the electron temperature Te [V] of plasma is illustrated in a graph of FIG. 6. Even if the inside of the frame Mu has the electron density Ne of the plasma and the electron temperature Te of the plasma when microwaves of 5 W are introduced, and low-power microwaves of about 5 W are introduced from one microwave introduction unit 43, it can be seen that the plasma is ignitable below the dielectric window portion 1a. Further, in the graph of FIG. 6, Ar gas and N₂ gas are supplied, and plasma is generated by the power of microwaves illustrated on the horizontal axis.

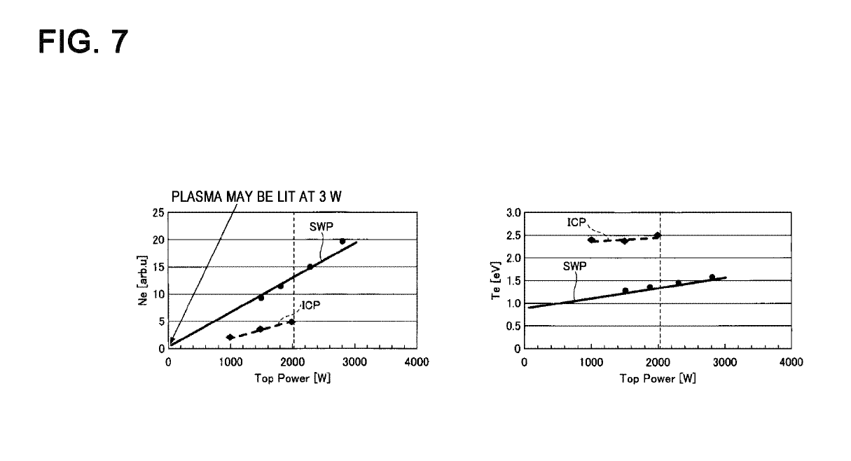

FIG. 7 is a graph illustrating the electron density Ne and the electron temperature Te of the surface wave of the microwaves generated by the microwave plasma processing apparatus (SWP) 100 according to the exemplary embodiment in comparison with the case of inductively coupled plasma processing apparatus (ICP). According to FIG. 7, the electron density Ne of the surface wave plasma of the microwaves is higher than the electron density Ne of the inductively coupled plasma. Further, in the microwave plasma processing apparatus 100 according to the exemplary embodiment, microwaves may be introduced from a plurality of microwave introduction units 43 (multi-plasma sources). Therefore, the microwaves output from each of the seven microwave introduction units 43 may be controlled to be low-power such that the total power introduced from each of the plurality of microwave introduction units 43 is 0.3 W/cm² or less. For example, in a case of the power of microwaves of 0.3 W/cm² in a wafer W of 300 mm, the total power of microwaves output from the plurality of microwave introduction units 43 is 135 W or less.

As a result, very weak plasma may be locally generated below the plurality of microwave introduction units 43. For example, in the graph on the left side of FIG. 7, the plasma may be lit even low-power microwaves of 3 W are introduced from each of the plurality of microwave introduction units 43. Thus, it is possible to generate very weak plasma.

Although microwaves may be introduced using at least one of the plurality of the microwave introduction units 43, more microwave introduction units 43 may be used. By introducing microwaves using more microwave introduction units 43, the power of the microwaves output from each one of the microwave introduction units 43 may be further lowered, so that weaker plasma may be generated.

Further, as illustrated by the electron density Ne in the graph on the left side of FIG. 7, in the inductively coupled plasma processing apparatus (ICP), when the maximum power of the introduced high frequency is 1000 W or less, plasma is not ignitable, and thus it is not possible to generate plasma. Meanwhile, in the microwave plasma processing apparatus (SWP) 100 according to the exemplary embodiment, even when the maximum power of the introduced microwaves is 1000 W or less, it is possible to generate plasma. That is, in the microwave plasma processing apparatus (SWP) 100 according to the exemplary embodiment, even when the maximum power of the introduced microwaves is between 3 W to 1000 W, plasma may be ignited, so that it is possible to generate plasma. For example, even when introducing microwaves having the maximum power of 3 W or more from each of the plurality of microwave introduction units 43, plasma is lit (ignited) as illustrated in (f) of FIG. 5.

Meanwhile, in the inductively coupled plasma processing apparatus (ICP), in order to light up stably the plasma capable of processing a wafer of 300 mm, a high frequency having the maximum power of 800 W or more is required.

Further, according to a graph on the right side of FIG. 7, the electron temperature Te of plasma generated by microwave plasma processing apparatus (SWP) 100 according to the exemplary embodiment is lower than the electron temperature of plasma generated by inductively coupled plasma processing apparatus (ICP) by 1 [eV] or more. Therefore, according to the microwave plasma processing apparatus 100 according to the exemplary embodiment, by introducing microwaves using the microwave introduction unit 43 such that the total power of introduced microwaves is 0.3 W/cm² or less, very weak plasma having a lower electron temperature Te of plasma may be generated. Such weak plasma may not be generated by the inductively coupled plasma processing apparatus (ICP) and a capacitively coupled plasma processing apparatus (CCP). That is, the microwave plasma processing apparatus (SWP) according to the exemplary embodiment is able to locally ignite plasma by low-power microwaves introduced from the plurality of microwave introduction units 43. Thereby, it is possible to avoid occurrence of charge-up damage when conveying the wafer W and damage of the wafer W due to plasma ignition during the processing by the very weak plasma generated.

### [Microwave Introduction Sequence]

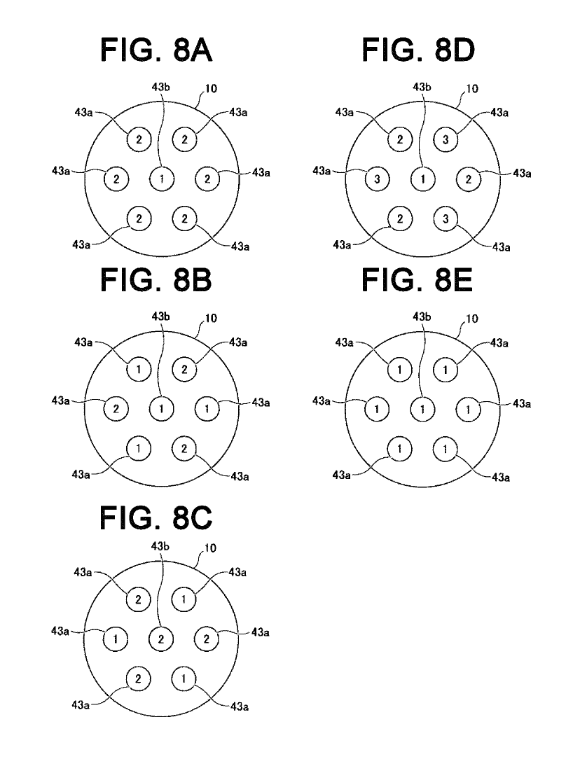

Finally, in the exemplary embodiment, an introduction sequence of microwaves radiated while plasma processing on the wafer W is not performed (e.g., during the conveyance of the wafer) will be described with reference to FIGS. 8A to 8E. In the microwave plasma processing apparatus 100 according to exemplary embodiment, microwaves are introduced into the processing container 1 from at least one of seven microwave introduction units 43 in total including six peripheral edge microwave introduction units 43a and one central microwave introduction unit 43b.

An example of microwave introduction sequence (sequence 1) is illustrated in FIG. 8A. In the sequence 1, first, microwaves are radiated from the central microwave introduction unit 43b, and plasma is ignited below the dielectric window portion 1a of the central microwave introduction unit 43b. Next, microwaves are radiated from the six peripheral edge microwave introduction units 43a, and plasma is ignited below the dielectric window portion 1a of the six peripheral edge microwave introduction units 43a.

In this manner, plasma may be ignited using the peripheral edge microwave introduction unit 43a after igniting the plasma using the central microwave introduction unit 43b. The reason is that, when plasma is ignited below the central microwave introduction unit 43b, plasma is easily ignited below the peripheral edge microwave introduction unit 43a, so that the plasma may be lit with a weaker power, therefore the influence at the time of plasma ignition to the wafer W may be further reduced.

However, the sequence is not limited thereto, and plasma may be lit by other sequences. In an example of the microwave introduction sequence 2 in FIG. 8B, first, microwaves are radiated from the central microwave introduction unit 43b and from three peripheral edge microwave introduction units 43a which are not adjacent each other in the circumferential direction. Thereafter, microwaves are radiated from the remaining three peripheral edge microwave introduction units 43a which are not adjacent each other in the circumferential direction.

In an example of the microwave introduction sequence 3 in FIG. 8C, first, microwaves are radiated from three peripheral edge microwave introduction units 43a which are not adjacent each other in the circumferential direction. Thereafter, microwaves are radiated from the central microwave introduction unit 43b and the remaining three peripheral edge microwave introduction units 43a which are not adjacent each other in the circumferential direction.

In an example of the microwave introduction sequence 4 in FIG. 8D, first, microwaves are radiated from the central microwave introduction unit 43b. Thereafter, microwaves are radiated from three peripheral edge microwave introduction units 43a which are not adjacent each other in the circumferential direction. Next, microwaves are radiated from the remaining three peripheral edge microwave introduction units 43a which are not adjacent each other in the circumferential direction.

In an example of the microwave introduction sequence 5 in FIG. 8E, microwaves are radiated from all the central microwave introduction unit 43b and the six peripheral edge microwave introduction units 43a at the same timing.

Further, as illustrated in FIGS. 8A to 8E, in the introducing sequence of microwaves radiated while the plasma processing is not performed on the wafer W (e.g., during the conveyance of the wafer), the sequence is not limited to a case in which microwaves are radiated from all the microwave introduction units 43. For example, microwaves may be radiated from some of the microwave introduction units 43. In any of the introduction sequences illustrated in FIGS. 8A to 8E or the case in which microwaves are radiated from some of the microwave introduction units 43, after loading the wafer, microwaves are radiated from all the microwave introduction units 43.

Further, in any of the introduction sequences illustrated in FIGS. 8A to 8E or the case in which microwaves are radiated from some of the microwave introduction units 43, while the plasma processing is not performed, the output of microwaves is controlled such that the total power is 0.3 W/cm² or less. On the other hand, while the plasma processing is performed on the wafer W, the microwave output using all the seven microwave introduction units 43 is controlled such that the total power of microwaves is 15.6 W/cm² or more. That is, in the exemplary embodiment, the total power of microwaves per unit area radiated while the plasma processing is not performed on the wafer W is controlled to be 1/50 or less of the total power of microwaves per unit area radiated while the processing is performed (i.e., while the plasma processing is performed on the wafer W). The period in which the plasma processing is not performed on the wafer W includes the period of conveying the wafer W.

As described above, according to the microwave plasma processing apparatus 100 according to the exemplary embodiment, by always lighting the very weak plasma, the damage to the wafer W due to the ignition of plasma may be avoided, and by loading/unloading the wafer while the very weak plasma is generated, the charge-up damage may be suppressed. Further, by avoiding damaging the wafer W, generation of particles may be avoided. In addition, since lighting on/off is unnecessary, the plasma processing step may be shortened. Further, particles may be reduced by capturing the particles by plasma. Moreover, during the processing, it is possible to perform a desired processing on the wafer W by raising the total power of microwaves and generating high density plasma.

In the present specification, the semiconductor wafer W has been described as an example of the substrate. However, the substrate is not limited to the semiconductor, and various substrates used for liquid crystal display (LCD), flat panel display (FPD), a photomask, a CD substrate, a printed board, or the like may be used.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

What is claimed is:

1. A plasma processing apparatus comprising:
a plurality of microwave radiating mechanisms configured to radiate microwaves output from an output unit in a surface wave plasma source into a processing container; and
a controller configured to generate plasma while a plasma processing is not performed on a substrate, by radiating microwaves with total power which is 1/50 or less of total power of microwaves per unit area radiated when plasma processing is performed on the substrate.

2. The plasma processing apparatus of claim 1, wherein the controller causes the microwaves to be radiated from at least one of the plurality of microwave radiation mechanisms with the total power of 1/50 or less of the total power of microwaves per unit area.

3. The plasma processing apparatus of claim 1, wherein the plurality of microwave radiation mechanisms are disposed at a center and an outer periphery of a ceiling plate of the processing container, and
the controller causes the microwaves to be radiated from the microwave radiation mechanism at the center, and then causes the microwaves to be radiated from at least one of the microwave radiation mechanisms at the outer periphery.

4. The plasma processing apparatus of claim 1, wherein the plurality of microwave radiation mechanisms are disposed at a center and an outer periphery of a ceiling plate of the processing container, and
the controller causes the microwaves to be radiated from at least one of the microwave radiation mechanisms at the outer periphery, and then causes the microwaves to be radiated from the microwave radiation mechanism at the center.

5. The plasma processing apparatus of claim 1, wherein the plurality of microwave radiation mechanisms are disposed at a center and an outer periphery of a ceiling plate of the processing container, and
the controller causes the microwaves to be radiated from the microwave radiation mechanism at the center and from a plurality of non-adjacent microwave radiation mechanisms disposed in the circumferential direction at the outer periphery, and then causes the microwaves to be radiated from at least one of remaining microwave radiation mechanisms at the outer periphery.

6. The plasma processing apparatus of claim 1, wherein the plurality of microwave radiation mechanisms are disposed at a center and an outer periphery of a ceiling plate of the processing container, and
the controller causes the microwaves to be radiated from the plurality of the non-adjacent microwave radiation mechanisms disposed in the circumferential direction at the outer periphery, and then causes the microwaves to be radiated from the microwave radiation mechanism at the center and from at least one of remaining microwave radiation mechanisms at the outer periphery.

7. The plasma processing apparatus of claim 1, wherein the plurality of microwave radiation mechanisms are disposed at a center and an outer periphery of a ceiling plate of the processing container, and
the controller causes the microwaves to be radiated from all the disposed microwave radiation mechanisms at a same timing.

8. The plasma processing apparatus of claim 1, wherein the controller controls the total power of microwaves per unit area to 0.3 W/cm² or less while the plasma processing is not performed on the substrate.

9. The plasma processing apparatus of claim 1, wherein the controller controls the total power of microwaves per unit area to 15.6 W/cm² or more while a plasma processing is performed on the substrate.

10. The plasma processing apparatus of claim 1, wherein the controller controls the total power of microwaves per unit area to 0.3 W/cm² or less and opens a gate valve so as to load the substrate into the processing container while plasma having an electron temperature of 1 [eV] or less is generated, and
after the substrate is loaded into the processing container, the controller closes the gate valve, controls the total power of microwaves per unit area to 15.6 W/cm² or more, and performs the plasma processing on the substrate.

11. The plasma processing apparatus of claim 10, wherein, after performing the plasma processing on the substrate, the controller controls the total power of microwaves per unit area to 0.3 W/cm² or less and opens the gate valve to unload the substrate from the processing container while plasma having an electron temperature of 1 [eV] or less is generated.
